(19) United States
(12) Patent Application Publication
(10) Pub. No.: US 2011/0226626 A1
(43) Pub. Date: Sep. 22, 2011

(54) APPARATUS AND METHOD FOR TREATING SUBSTRATE

(75) Inventors: Ju-il Choi, Suwon-si (KR); Uihyoung Lee, Seoul (KR); Jae-hyun Phee, Gyeyang-gu (KR); Jeong-Woo Park, Suwon-si (KR)

(73) Assignee: SAMSUNG ELECTRONICS CO., LTD., Suwon-si (KR)

(21) Appl. No.: 13/039,822

(22) Filed: Mar. 3, 2011

(30) Foreign Application Priority Data
Mar. 22, 2010 (KR) 1020100025440

(51) Int. Cl. C25D 5/48; H01L 21/306

(52) U.S. Cl. 205/93; 156/345.21

(57) ABSTRACT

A substrate treating device may include a plating treatment portion configured to perform a plating process of a substrate, a wet treatment portion configured to perform a wet treating process of the substrate, the wet treatment portion being under the plating treatment portion, and a substrate support portion configured to support the substrate so that a plating surface of the substrate faces upward, the substrate support portion being further configured to move the substrate between the plating treatment portion and the wet treatment portion.

### CROSS-REFERENCE TO RELATED APPLICATIONS

This U.S. non-provisional patent application claims priority under 35 U.S.C. §119 of Korean Patent Application No. 10-2010-0025440, filed on Mar. 22, 2010, the entire contents of which are hereby incorporated by reference.

### BACKGROUND

1. Field

The inventive concepts described herein relate to apparatuses and methods for treating a substrate, and more particularly, to an apparatus and a method for plating a semiconductor substrate with metal.

2. Description of the Related Art

Generally, an electroplating apparatus connects a substrate and a plating material (e.g., copper) to a power supply to form a metal layer on the substrate by an electrochemical reaction. There are several processes (e.g., a chemical vapor deposition, a physical vapor deposition etc.) of forming a metal layer on a substrate but a property of a metal layer formed by an electroplating method is superior to a property of a metal layer formed by other processes. Thus, an electroplating method is being used as a standard process of forming a metal layer on a substrate.

### SUMMARY

In accordance with an example embodiment of the inventive concepts, a substrate treating device may include a plating treatment portion configured to perform a plating process on a substrate, a wet treatment portion configured to perform a wet treating process on the substrate, the wet treatment portion being under the plating treatment portion, and a substrate support portion configured to support the substrate so that a plating surface of the substrate faces upward, the substrate support portion being further configured to move the substrate between the plating treatment portion and the wet treatment portion.

In accordance with example embodiments of the inventive concepts, a method of treating a substrate may include supporting the substrate so that a plating surface of the substrate faces upward, moving the substrate up to a plating bath, performing a plating treatment on the substrate in the plating bath, moving the substrate down and into a collection container, the collection container being under the plating bath, and performing a wet treatment on the substrate using a spin method.

In accordance with an example embodiment of the inventive concepts, a substrate treating device may include a plating treatment portion performing a plating process of a substrate, a wet treatment portion performing a wet treating process of the substrate, the wet treatment portion being provided under the plating treatment portion, and a substrate support portion supporting the substrate so that a plating surface faces upward and moving the substrate between the plating treatment portion and the wet treatment portion.

In accordance with an example embodiment of the inventive concepts a method may include supporting a substrate so that a plating surface of the substrate faces upward, moving up the substrate to perform a plating treatment on the substrate in the plating bath, and moving down the substrate into a collection container disposed under the plating bath to perform a wet treatment on the substrate using a spin method.

### BRIEF DESCRIPTION OF THE DRAWINGS

The accompanying drawings are included to provide a further understanding of the inventive concepts, and are incorporated in and constitute a part of this specification. The drawings illustrate example embodiments of the inventive concepts and, together with the description, serve to explain principles of the inventive concepts. In the figures:

FIG. 1 is a top plan view of a substrate treating apparatus in accordance with an example embodiment of the inventive concepts.

FIG. 2 is a top plan view illustrating an internal structure of a process chamber illustrated in FIG. 1.

FIG. 3 is a cross-sectional view of a substrate treating portion illustrated in FIG. 2.

FIG. 4 is a cross-sectional view of a substrate supporting portion illustrated in FIG. 3.

FIG. 5 is an enlarged view of “A” portion of a nozzle arm illustrated in FIG. 2.

FIG. 6 is an enlarged view of “B” portion of a nozzle arm illustrated in FIG. 2.

FIG. 7 is a view illustrating an electrical connection state between an anode electrode and a substrate.

FIGS. 8A through 8D are views illustrating a process of forming a metal interconnection on a substrate.

FIGS. 9 through 16 are views illustrating a process of treating a substrate using a substrate treating apparatus in accordance with an example embodiment of the inventive concepts.

### DETAILED DESCRIPTION OF THE EXAMPLE EMBODIMENTS

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described. Hereinafter, example embodiments of the inventive concepts will be described in detail with reference to the drawings.

Example embodiments of the inventive concepts will be described below in more detail with reference to the accompanying drawings. The example embodiments of the inventive concepts may, however, be embodied in different forms and should not be constructed as limited to the example embodiments set forth herein. Rather, example embodiments are provided so that this disclosure will be thorough and complete, and will fully convey the scope of the inventive concept to those skilled in the art. Like numbers refer to like elements throughout.

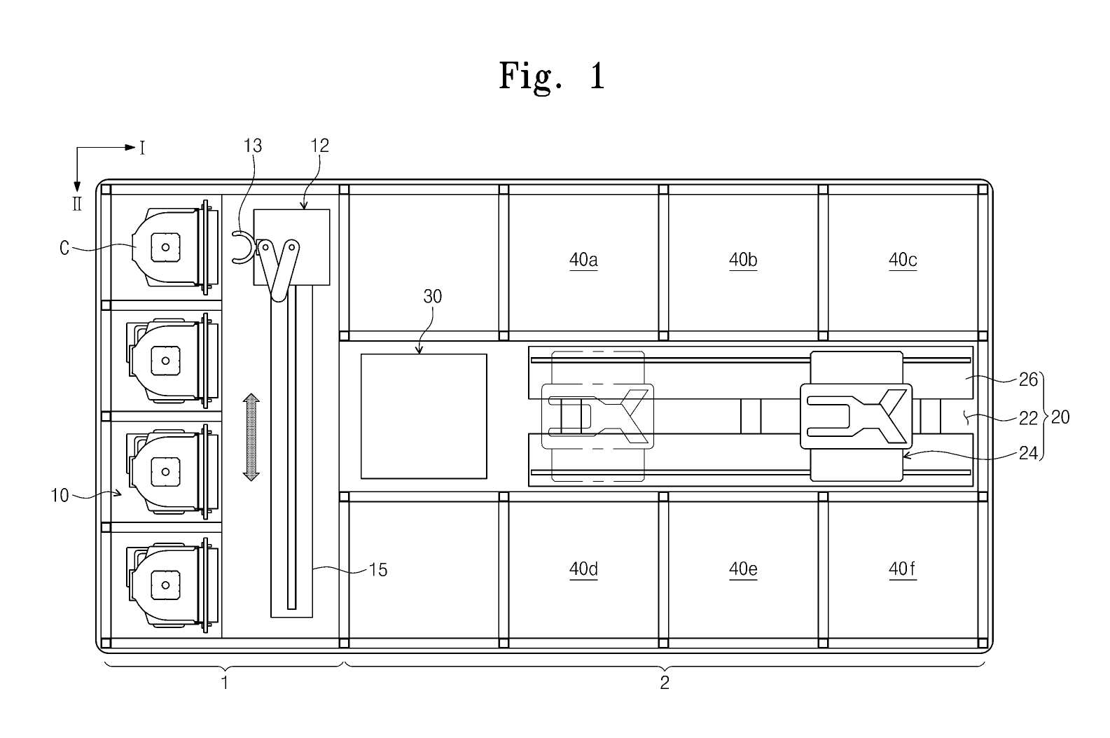

FIG. 1 is a top plan view of a substrate treating apparatus in accordance with an example embodiment of the inventive concepts.

Referring to FIG. 1, a substrate treating apparatus includes an equipment front-end module 1 and a process facility 2. The process facility 2 performs a substrate treating process using a single wafer process. The equipment front-end module 1 is installed at the front of the process facility 2 along a first direction (I) and transfers a substrate between a vessel (C) receiving substrates and the process facility 2.

The equipment front-end module 1 has a plurality of load ports 10 and at least one frame 12. The load ports 10 are disposed along a second direction (II) perpendicular to the first direction (I). The vessel (C) receiving substrates is placed on the load port 10 by a transferring means (not illustrated) such as an overhead transfer. The vessel (C) may be a sealed vessel such as a front open unified pod (FOUP). Substrates received in the vessel (C) may be semiconductor wafers. A conductive seed layer is provided to a treating surface (i.e., a plating surface) of semiconductor wafer and a photoresist pattern may be provided to a top surface of the seed layer.

The frame 12 is located between the load ports 10 and the process facility 2 and a longitudinal direction of the frame 12 is the second direction (II). A frame robot 13 and a door opener (not illustrated) are disposed in the frame 12. The frame robot 13 moves along a first transferring rail 15 extending in the second direction (II) and transfers a substrate between the vessel (C) placed on the load port 10 and the process facility 2. The door opener (not illustrated) opens and closes the door of the vessel (C).

The process facility 2 includes a substrate transferring unit 20, a buffer unit 30 and a plurality of process chambers (40a, 40b, . . . , 40e). The substrate transferring unit 20 has a transferring path 22 disposed along the first direction (I) at the other side of the equipment front-end module 1. A main transferring robot 24 is disposed in the transferring path 22. The main transferring robot 24 moves in the first direction (I) along a second transferring rail 26.

The buffer unit 30 is disposed between the substrate transferring unit 20 and the equipment front-end module 1 and provides a space in which a substrate being loaded to the process facility 2 and a substrate being unloaded from the process facility 2 temporarily stay.

The process chambers (40a, 40b, . . . , 40e) are disposed at both sides of the substrate transferring unit 20 along the second direction (II) and may have a multilevel structure of a plurality of levels stacked vertically. The process chambers (40a, 40b, . . . , 40e) perform a substrate treating process by a single wafer process. The substrate treating process may include a pre-wet process performed before a plating process, the plating process and a photoresist removing process, a seed layer etching process and a rinse and dry process that are subsequent processes of the plating process.

The frame robot 13 takes a substrate to be treated out of the vessel (C) and loads the substrate into the buffer unit 30. The main transferring robot 24 loads the substrate loaded in the buffer unit 30 into the process chambers (40a, 40b, . . . , 40e). The process chambers (40a, 40b, . . . , 40e) perform a pre-wet process performed before a plating process, the plating process and a photoresist removing process, a seed layer etching process and a rinse and dry process that are subsequent processes of the plating process.

The main transferring robot 24 takes the treated substrate out of the process chambers (40a, 40b, . . . , 40e) and loads the treated substrate into the buffer unit 30. The frame robot 13 takes the treated substrate out of the buffer unit 30 and loads the treated substrate into the vessel (C).

Since the process chambers (40a, 40b, . . . , 40e) have the same structure, hereinafter, one of those chambers will be described by example.

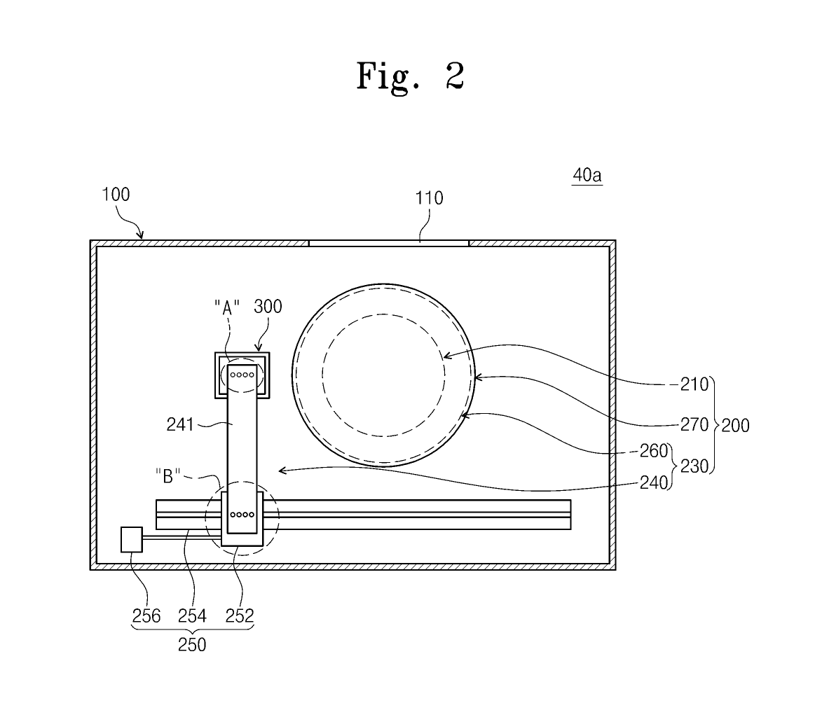

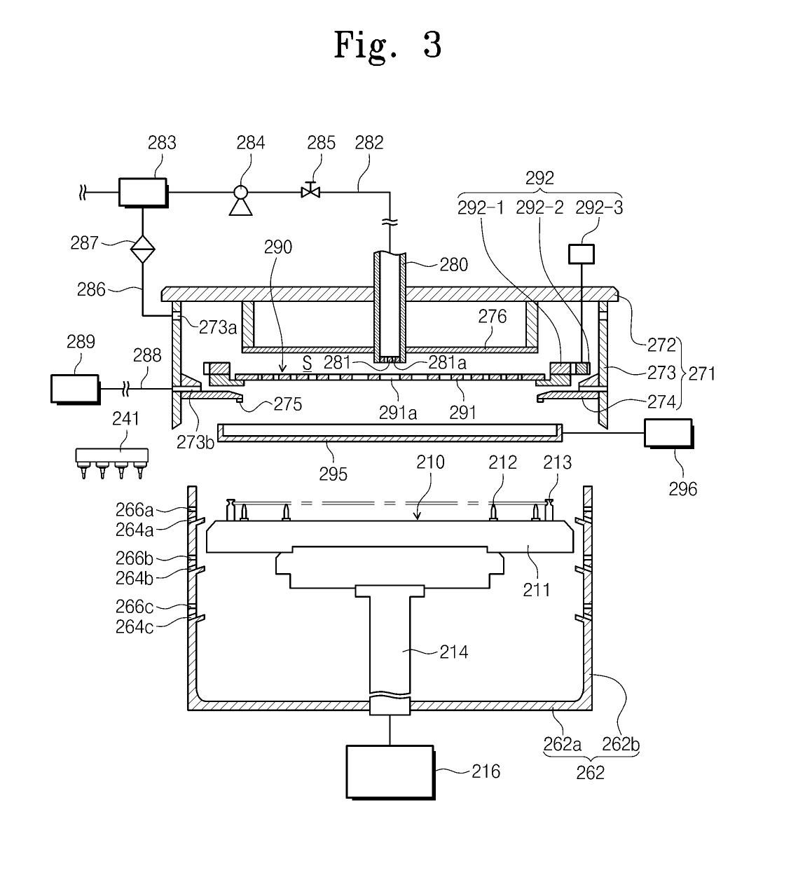

FIG. 2 is a top plan view illustrating an internal structure of a process chamber illustrated in FIG. 1. FIG. 3 is a cross-sectional view of a substrate treating portion illustrated in FIG. 2. Referring to FIGS. 2 and 3, the process chamber 40a includes a treating room 100, a substrate treating portion 200 and a standby port 300. The treating room 100 accommodates the substrate treating portion 200 and the standby port 300. An opening 110 is formed on one sidewall of the treating room 100 for bringing a substrate into the treating room 100 and taking a substrate out of the treating room 100 and the opening 110 is opened and closed by a gate valve (not illustrated).

The substrate treating portion 200 includes a substrate support portion 210, a wet treatment portion 230 and a plating treatment portion 270. The substrate support portion 210 supports a substrate so that a plating surface of the substrate faces upward and transfers the substrate between the wet treatment portion 230 and the plating treatment portion 270. The wet treatment portion 230 performs a pre-wet process performed before a plating process, and a photoresist removing process, a seed layer etching process and a rinse and dry process that are subsequent processes of the plating process.

The pre-wet process is a process providing a deionized (DI) water to a plating surface so that the plating surface of the substrate has a hydrophilic property. The plating process is a process that deposits a metal layer between photoresist patterns on a plating surface of the substrate using an electrode and a plating solution containing additives. The photoresist removing process is a process that removes a photoresist using organic solvents after a plating process. The seed layer etching process is a process that etches a seed layer existing everywhere except a lower portion of a plated metal layer using an etching solution. The rinse and dry process can be respectively performed after the plating process, the photoresist removing process and the seed layer etching process. The rinse process is a process that rinses a plating solution, an organic solvent and an etching solution using deionized (DI) water. The dry process is a process that dries the deionized (DI) water used in the rinse process using dry gas.

The substrate support portion 210 supports a substrate so that a plating surface of the substrate faces upward. The substrate support portion 210 has a spin chuck 211 of a disc shape. Support pins 212 and chuck pins 213 are coupled to the spin chuck 211. The support pins 212 protrude upwardly from a top surface of the spin chuck 211 and support a bottom surface (i.e., a surface which is not plated) of the substrate. The chuck pins 213 are disposed at plurality of places along the edge of the spin chuck 211 and protrude upwardly from a top surface of the spin chuck 211. The chuck pins 213 support a side portion of the substrate so that the substrate is aligned with a reference position and the substrate does not breakaway from the reference position to a side direction when the spin chuck 211 rotates. A driving shaft 214 is coupled to a bottom surface of the spin chuck 211. The driving shaft 214 can be rotated and moved up and down by a driver 216.

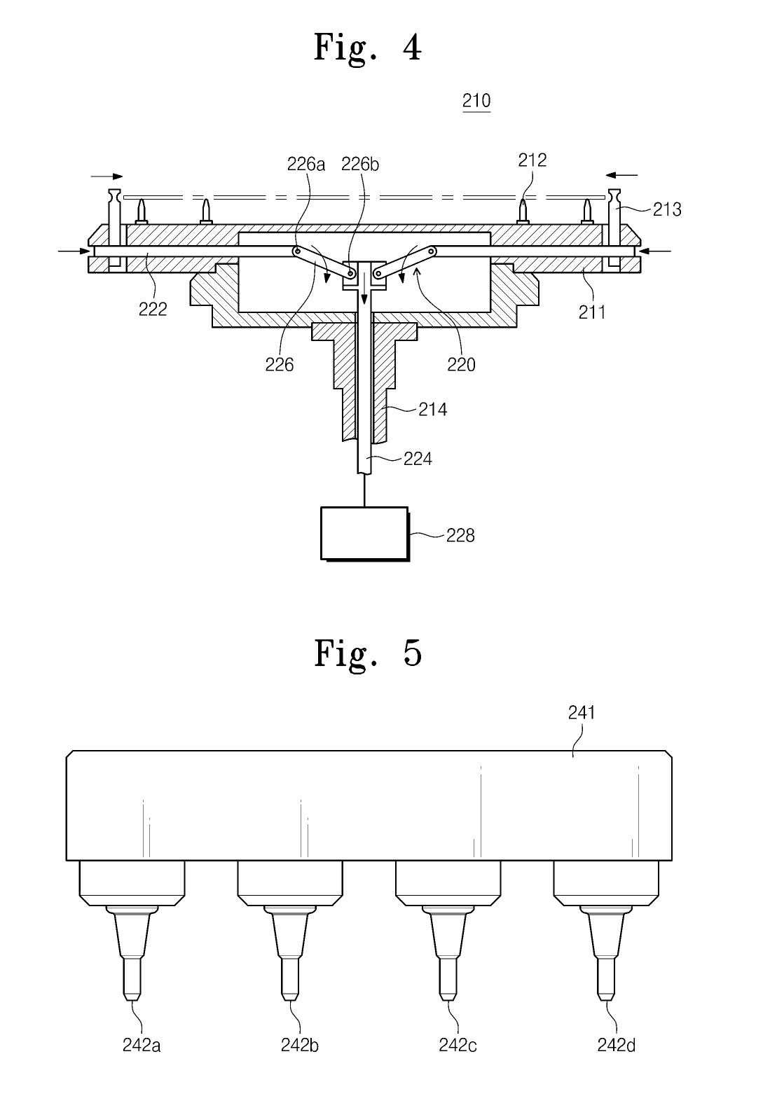

FIG. 4 is a cross-sectional view of a substrate supporting portion illustrated in FIG. 3. Referring to FIG. 4, a chuck pin moving unit 220 moves the chuck pins 213 between a support position supporting a side portion of the substrate and a standby position spaced farther apart from a center of the spin chuck 211 compared with the support position. The chuck pin moving unit 220 includes moving rods 222, a vertical rod 224, connection members 226, and a vertical rod driving portion 228. The moving rods 222 are provided to the inside of the spin chuck 211 and are horizontally disposed in radial directions on the basis of the center of the spin chuck 211. The chuck pin 213 is coupled to an external one end of the moving rod 222. The vertical rod 224 is provided to the inside of the support shaft 214 and can move up and down. The connection members 226 may have a bar shape. One end of the connection member 226 is hinge-connected to the other end of the moving rod 222 by a first hinge shaft 226a and the other end of the connection member 226 is hinge-connected to an upper portion of the vertical rod 224 by a second hinge shaft 226b. The vertical rod 224 is moved up and down by the vertical rod driving portion 228.

If the vertical rod 224 is moved down by the vertical rod driving portion 228, the second hinge shaft 226b moves down, the first hinge shaft 226a moves in a direction toward the center of the spin chuck 211 and the connection member 226 rotates using the first and second hinge shafts 226a and 226b as the axis of the rotation while an inclined angle of the connection member 226 becomes relatively large. The moving rod 222 is horizontally moved to the inner side toward the center of the spin chuck 211 by a movement of the first hinge shaft 226a and thereby the chuck pin 213 moves to the support position.

Alternatively, if the vertical rod 224 is moved up by the vertical rod driving portion 228, the second hinge shaft 226b moves up, the first hinge shaft 226a moves in a direction toward the edge of the spin chuck 211 and the connection member 226 rotates using the first and second hinge shafts 226a and 226b as the axis of the rotation while an inclined angle of the connection member 226 becomes relatively small. The moving rod 222 horizontally is moved to the outer side toward the edge of the spin chuck 211 by a movement of the first hinge shaft 226a and thereby the chuck pin 213 moves to the standby position.

Referring back to FIGS. 2 and 3, the wet treatment portion 230 performs a wet treating process on the substrate. For example, the wet treating process includes a pre-wet process, a photoresist removing process, a seed layer etching process and a rinse and dry process.

The wet treatment portion 230 includes a treating fluid supply member 240 and a treating fluid collection member 260. The treating fluid supply member 240 provides a treating fluid used in a wet treating process to a substrate loaded to the substrate support portion 210. The treating fluid collection member 260 collects a treating fluid being displaced by a rotation of the substrate.

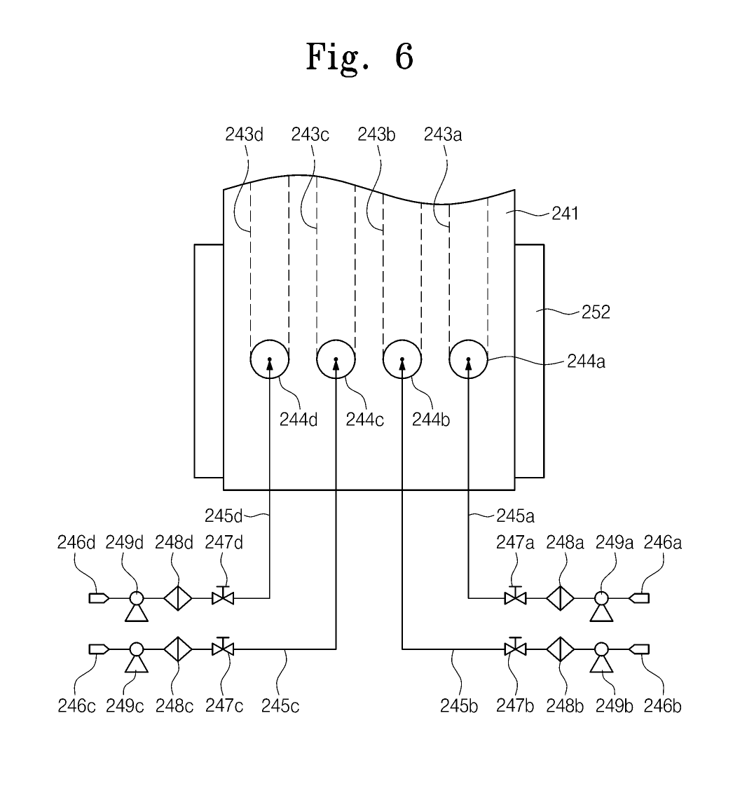

The treating fluid supply member 240 includes a nozzle arm 241, a plurality of nozzles 242a, 242b, 242c and 242d (see FIG. 5), and a nozzle arm driving portion 250. The nozzle arm 241 has a long rod shape. A lengthwise direction of the nozzle arm 241 is perpendicular to an arrangement direction of the substrate treating portion 200 and the standby port 300. A plurality of nozzles 242a, 242b, 242c and 242d, as shown in FIG. 5, are vertically installed at one end of the nozzle arm 241. The plurality of nozzles 242a, 242b, 242c and 242d may be disposed in a line along a direction perpendicular to the lengthwise direction of the nozzle arm 241. A deionized (DI) water nozzle 242a provides a deionized (DI) water to the substrate. A dry gas nozzle 242b provides a dry gas to the substrate. A nitrogen gas may be used as a dry gas. An organic solvent nozzle 242c provides an organic solvent for photoresist removal to the substrate. N-methyl pyrrolidinone (NMP), dimethyl sulfoxide (DMSO) and tetramethyl ammonium hydroxide (TMAH) may, for example, be used as an organic solvent. An etching solution nozzle 242d provides an etching solution to the substrate. When etching a seed layer having copper material, sulfuric acid or hydrogen peroxide may be used as an etching solution and when etching a seed layer having titanium (Ti) material, hydrofluoric acid or hydrogen peroxide may be used as an etching solution.

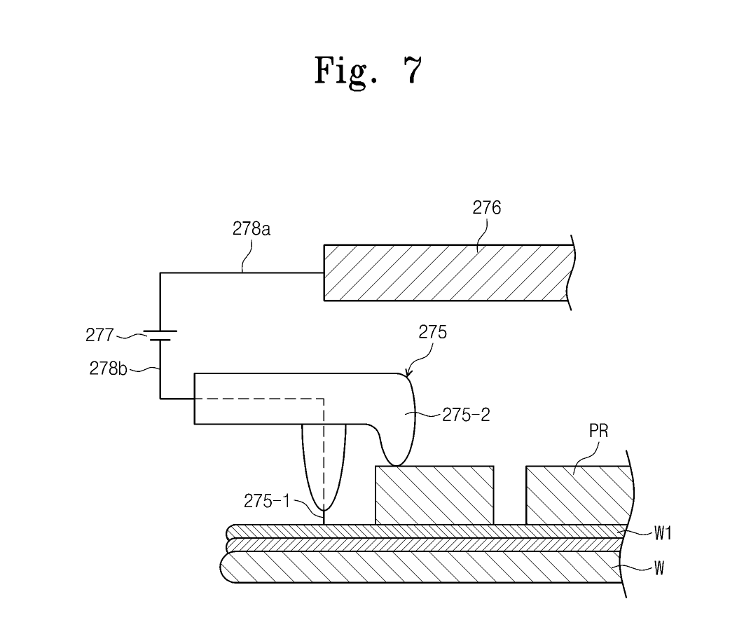

Pipes 243a, 243b, 243c and 243d, as illustrated in FIG. 6, are built in the nozzle arm 241. The pipes 243a, 243b, 243c and 243d include a deionized (DI) water pipe 243a, a dry gas pipe 243b, an organic solvent pipe 243c and an etching solution pipe 243d. The pipes 243a, 243b, 243c and 243d are disposed in a lengthwise direction of the nozzle arm 241 in the nozzle arm 241. One end of the deionized (DI) water pipe 243a is connected to the deionized (DI) water nozzle 242a and the other end of the deionized (DI) water pipe 243a is connected to a deionized (DI) water inflow port 244a. One end of the dry gas pipe 243b is connected to the dry gas nozzle 242b and the other end of the dry gas pipe 243b is connected to a dry gas inflow port 244b. One end of the organic solvent pipe 243c is connected to the organic solvent nozzle 242c and the other end of the organic solvent pipe 243c is connected to an organic solvent inflow port 244c. One end of the etching solution pipe 243d is connected to the etching solution nozzle 242d and the other end of the etching solution pipe 243d is connected to an etching solution inflow port 244d.

The inflow ports 244a, 244b, 244c and 244d are provided to the other end of the nozzle arm 241. The deionized (DI) water inflow port 244a provides an inlet through which a deionized (DI) water flows into the deionized (DI) water pipe 243a. The dry gas inflow port 244b provides an inlet through which a dry gas flows into the dry gas pipe 243b. The organic solvent inflow port 244c provides an inlet through which an organic solvent flows into the organic solvent pipe 243c. The etching solution inflow port 244d provides an inlet through which an etching solution flows into the etching solution pipe 243d.

One end of a deionized (DI) water supply line 245a is connected to the deionized (DI) water inflow port 244a and the other end of the deionized (DI) water supply line 245a is connected to a source of deionized (DI) water 246a. A valve 247a, a filter 248a and a pump 249a are installed on the deionized (DI) water supply line 245a. One end of a dry gas supply line 245b is connected to the dry gas inflow port 244b and the other end of the dry gas supply line 245b is connected to a source of dry gas 246b. A valve 247b, a filter 248b and a pump 249b are installed on the dry gas supply line 245b. One end of an organic solvent supply line 245c is connected to the organic solvent inflow port 244c and the other end of the organic solvent supply line 245c is connected to a source of organic solvent 246c. A valve 247c, a filter 248c and a pump 249c are installed on the organic solvent supply line 245c. One end of an etching solution supply line 245d is connected to the etching solution inflow port 244d and the other end of the etching solution supply line 245d is connected to a source of etching solution 246d. A valve 247d, a filter 248d and a pump 249d are installed on the etching solution supply line 245d.

The nozzle arm driving portion 250 may include a support member 252, a guide member 254 and a driver 256. The support member 252 may have a rod shape. The support member 252 is vertically disposed so that the support member 252 is maintained to be perpendicular to the nozzle arm 241 and an upper portion of the support member 252 is coupled to the other end of the nozzle arm 241. A lower portion of the support member 252 is coupled to the guide member 254. The guide member 254 may have a guide rail shape. The driver 256 provides a linear driving power to the support member 252. In this example, the driver 256 may be comprised of a cylinder that is configured to extend and contract (i.e., move, linearly, back and forth). However, the inventive concepts are not limited thereto. For example, the driver 256 may be comprised of an assembly constituted by a combination of a motor and a gear. The driver 256 linearly moves the support member 252 and a linear movement of the support member 252 is guided by the guide member 254. As a result, the nozzle arm 241 linearly moves and the nozzles 242a, 242b, 242c and 242d coupled to one end of the nozzle arm 241 move between a standby position on the standby port 300 and a process position on an upper portion of a substrate. The support member 252 may be linearly moved up and down by a driver (not illustrated).

The treating fluid collection member 260 collects a treating fluid displaced by a rotation of a substrate during a wet treating process of a substrate. The treating fluid collection member 260 includes a collection container 262, collection holes 264a, 264b and 264c and exhaust holes 266a, 266b and 266c. The collection container 262 has a container shape of which an upper portion is open and surrounds the substrate support portion 210 located at descended position. More specifically, the collection container 262 has a bottom wall 262a and a vertical sidewall 262b extending in an upward direction from a periphery portion of the bottom wall 262a. The driving shaft 214 of the substrate support portion 210 is inserted into a hole formed in the center of the bottom wall 262a.

The collection holes 264a, 264b and 264c separately collect displaced treating fluids (i.e., a deionized (DI) water, an organic solvent and an etching solution). The collection holes 264a, 264b and 264c are provided at different heights of the vertical sidewall 262b. The first collection hole 264a is disposed at a higher position than the second collection hole 264b. The second collection hole 264b is disposed at a higher position than the third collection hole 264c. The first collection hole 264a can collect deionized water, the second collection hole 264b can collect an organic solvent and the third collection hole 264c can collect an etching solution. Tanks (not illustrated) storing the collected treating fluids are connected to the first to the third collection holes 264a, 264b and 264c, respectively.

The exhaust holes 266a, 266b and 266c separately exhaust the atmosphere including a dry gas and an organic solvent ingredient and the atmosphere including an etching solution ingredient. The exhaust holes 266a, 266b and 266c are provided at different heights of the vertical sidewall 262b. The first exhaust hole 266a is disposed above the first collection hole 264a and can exhaust a dry gas. The second exhaust hole 266b is disposed above the second collection hole 264b and can exhaust the atmosphere including an organic solvent. The third exhaust hole 266c is disposed above the third collection hole 264c and can exhaust the atmosphere including an etching solution. Tanks (not illustrated) for storing the exhausted gas are connected to the first to the third exhaust holes 266a, 266b and 266c, respectively.

The plating treatment portion 270 performs a plating treating process of a substrate. The plating treatment portion 270 has a plating bath 271. The plating bath 271 is disposed above the collection container 262 and provides a space S in which a plating process of a substrate is performed. The plating bath 271 includes a top wall 272, a sidewall 273 extending in a downward direction from an edge of the top wall 272 and a contact plate 274 of a ring shape coupled to a lower portion of the sidewall 273. A contact portion 275 is provided to an internal circumference portion of bottom surface of the contact plate 274 and a substrate is in contact with the contact portion 275 by ascending of the substrate support portion 210.

An anode electrode 276 is horizontally disposed above the contact plate 274. The anode electrode 276 may have a disc shape. A hole into which a plating solution injection nozzle 280 is inserted is formed at the center of the anode electrode 276. The anode electrode 276 is provided as a metal plate having property of a plating material.

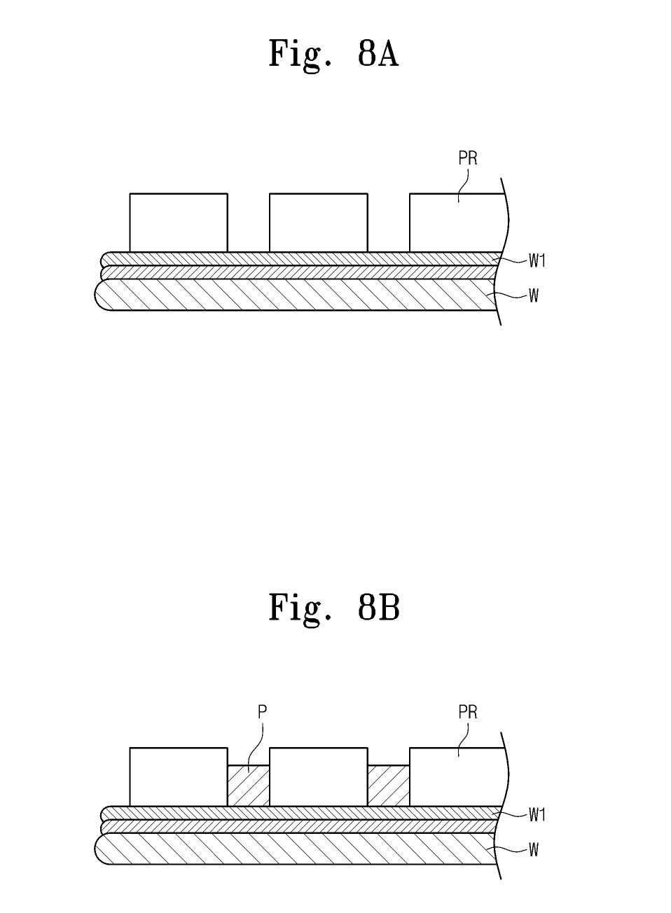

The anode electrode 276 and a substrate W, as illustrated in FIG. 7, receive a voltage from a power supply 277. More specifically, a positive pole of the power supply 277 is connected to the anode electrode 276 by a first conducting wire 278a and a negative pole of the power supply 277 is connected to metal pins 275-1 of the contact portion 275 by a second conducting wire 278b. The contact portion 275 includes the metal pins 275-1 and a sealing member 275-2. The sealing member 275-2 may be provided in a ring shape having an L-shaped cross section (e.g. “ [symbol] ” shape) and may be coupled to an internal circumference portion of a bottom surface of the contact plate 274. The sealing member 275-2 is in contact with a photoresist layer PR on the substrate W to prevent a plating solution being provided to the substrate W from leaking into an edge of the substrate W. The metal pins 275-1 may be installed at a plurality of positions along a circumferential direction of the contact plate 274 and can be connected to the second conducting wire 278b through the sealing member 275-2. An end portion of the metal pin 275-1 is in contact with a conductive seed layer W1 of an edge of the substrate W.

The plating solution injection nozzle 280 may be provided as a pipe of hollow shape. The plating solution injection nozzle 280 is arranged in a vertical direction and inserted into a hole formed at the top wall 172 of the plating bath 271. The plating solution injection nozzle 280 may be inserted into a hole of the anode electrode 276 so that a lower portion of the plating solution injection nozzle 280 protrudes downwardly from the anode electrode 276. An injection plate 281 is provided to a lower portion of the plating solution injection nozzle 280. A plurality of injection holes 281a is formed at the injection plate 281. A plating solution injected from the plating solution injection nozzle 280 can be uniformly injected through the injection holes 281a. A plating space S formed by the sidewall 273, the contact plate 274 and the substrate is filled with a plating solution being injected through the injection plate 281. The plating solution injection nozzle 280 is connected to a plating solution tank 283 by a plating solution supply line 282. A pump 284 and a valve 285 are disposed on the plating solution supply line 282.

An overflow hole 273a for overflowing a plating solution while performing a plating process is formed on the sidewall 273. One end of a circulation line 286 is connected to the overflow hole 273a and the other end of the circulation line 286 is connected to the plating solution tank 283. A filter 287 is disposed on the circulation line 286. When a level of a plating solution in the plating space S reaches the overflow hole 273a, the plating solution is drained through the overflow hole 273a. A plating solution being drained flows in the plating solution tank 283 through the circulation line 286 and impurities included in the plating solution are removed through the filter 287. A plating solution flowed in the plating solution tank 283 can be resupplied to the plating solution injection nozzle 280 through the plating solution supply line 282. A discharge hole 273b may be formed on the sidewall 273 on the upper portion of the contact plate 274. The discharge hole 273b discharges a plating solution in the plating bath 271 after a plating process is completed in the plating bath 271. One end of a discharge line 288 is connected to the discharge hole 273b and the other end of the discharge line 288 is connected to a tank 289 for storing a discharged plating solution.

A plating solution agitation member 290 is disposed between the contact plate 274 and the anode electrode 276. The plating solution agitation member 290 agitates a plating solution being provided to the substrate. A plating process can be performed on a pattern having a high aspect ratio without generating bubble by an agitation of a plating solution.

The plating solution agitation member 290 has an agitation plate 291 having a disc shape horizontally disposed under the anode electrode 276. A plurality of penetration holes 291a through which a plating solution passes is formed on the agitation plate 291. A size of the penetration holes 291a may become gradually small as going from the center of the agitation plate 291 to a circumference of the agitation plate 291. The amount of plating deposition increases at the center of the substrate by providing more plating solutions to the center of the substrate and forming a higher electric field. As a result, the plating layer is uniformly deposited. The agitation plate 291 is rotated using the central axis of the agitation plate as the central axis of a rotation by a plate driving portion 292.

The plate driving portion 292 includes a driven gear 292-1 of a ring shape supporting an edge of bottom surface of the agitation plate 291 and having a tooth form on an external circumference surface thereof, a driving gear 292-2 having a disc shape engaging with the driven gear 292-1 and a rotation driver 292-3 providing a rotational force to the driving gear 292-2.

A drip bath 295 is disposed between the plating bath 271 and the collection container 262. The drip bath 295 moves between a space between the plating bath 271 and the collection container 262 and the outside of the space by a driving portion 296. When a plating process is performed, the drip bath 295 moves to the outside of the space between the plating bath 271 and the collection container 262. When a wet treating process is performed, the drip bath 295 moves to the space between the plating bath 271 and the collection container 262 to receive a plating solution dropping from the plating bath 271.

The standby port 300 is provided to one side of the substrate treating portion 200 and provides a place on which nozzles 242a, 242b, 242c and 242d of the treating fluid supply member 240 are in standby to perform a process.

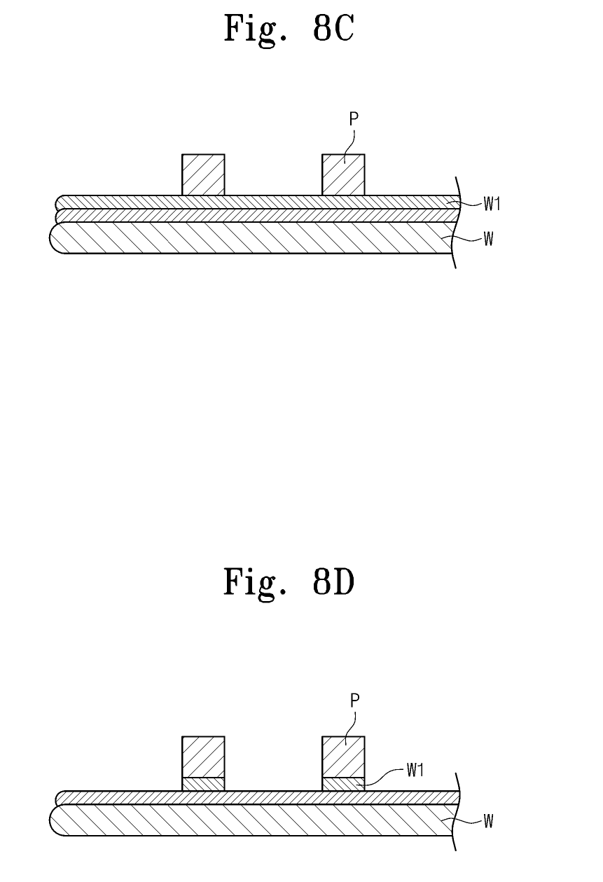

FIGS. 8A through 8D are views illustrating a process of forming a metal interconnection on a substrate. Referring to FIGS. 8A through 8D, a conductive seed layer W1 is provided on a top surface of a substrate W (i.e., a plating surface) and a photoresist pattern PR is provided on a top surface of the seed layer W1. A plating layer P is formed in a space between the photoresist pattern PR by a plating process. After the plating process, the photoresist pattern PR is removed, and then the seed layer is etched except the seed layer under the plating layer P.

Hereinafter, performing the above-described processes will be described using the substrate treating device in accordance with an example embodiment of the inventive concepts.

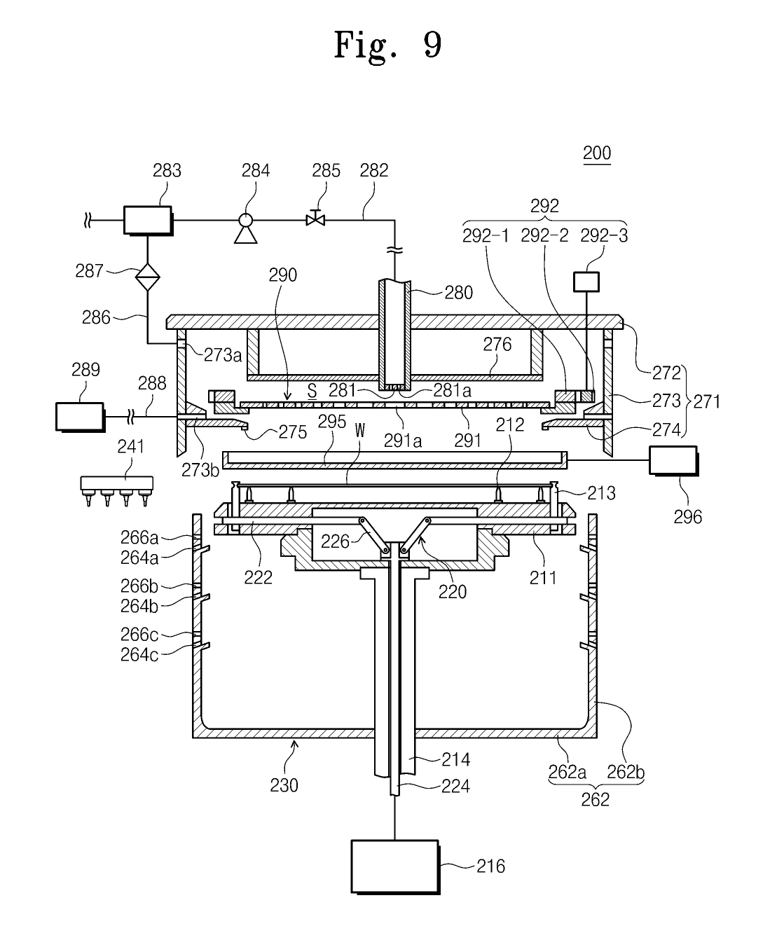

FIGS. 9 through 16 are views illustrating a process of treating a substrate using a substrate treating apparatus in accordance with an example embodiment of the inventive concepts. Referring to FIG. 2 and FIGS. 9 through 16, a process of treating a substrate can be performed in the order of a substrate loading, a wet process, a plating process, a rinse and dry process, a photoresist removing process, an etching process and a substrate unloading process.

The spin chuck 211 is moved upwardly by the shaft driver 216 so that the supporting pins 212 and the chuck pins 213 protrude upwardly from an upper portion of the collection container 262. A substrate W is placed on the supporting pins 212 by the main transferring robot 24 as a state in which a plating surface of the substrate W faces upward. (FIG. 9). The vertical rod 224 may be lowered causing the moving rods 222 to move inward thus moving the chuck pins 213 in a position to support the substrate W.

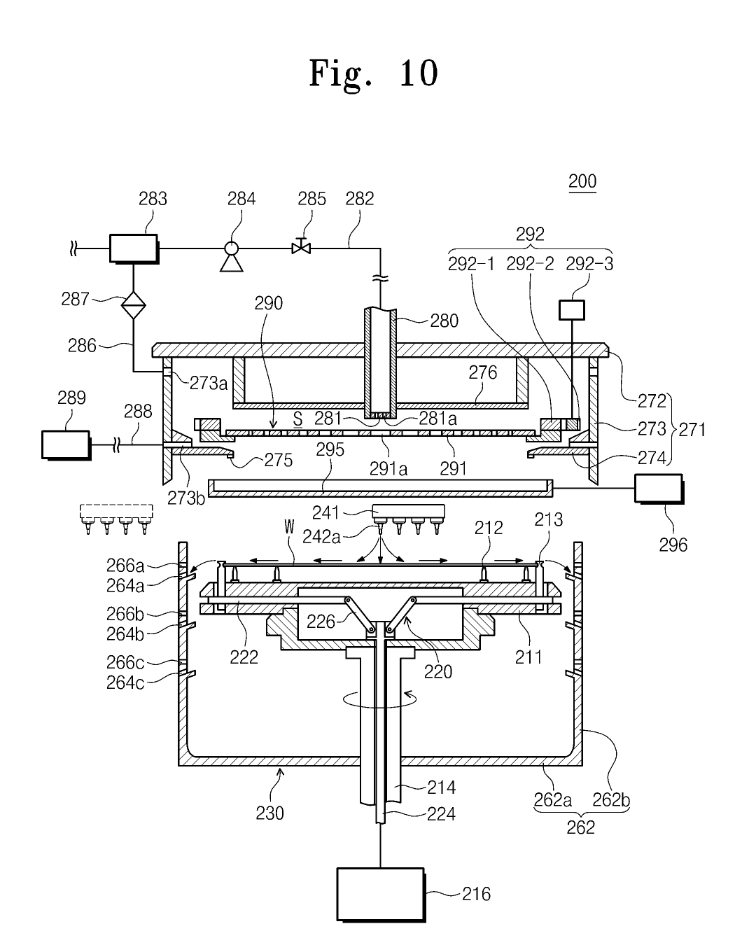

In FIG. 9, a side portion of the substrate W placed on the support pins 212 is supported by the chuck pins 213. The substrate W can be aligned with a reference position while being supported by the chuck pins 213. The chuck driver 216 causes the spin chuck 211 to move down to a first position where a wet etching is performed. The deionized water nozzle 242a is located at the center of the upper portion of the substrate W by a linear movement of the nozzle arm 241. The deionized water nozzle 242a injects deionized water for a wet process onto a plating surface of the substrate W and the substrate W rotates as the spin chuck 211 is rotated by the chuck driver 216. Deionized water being displaced by a rotation of the substrate W is collected through the first collection hole 264a. (FIG. 10).

If a wet processing is completed, the drip bath 295 moves to the outside of a space between the collection container 262 and the plating bath 271 by the driving portion 296. The spin chuck 211 moves upward to a position in which a plating process is being performed by the shaft driver 216. At this time, an edge of the substrate W is in contact with the contact portion 275 provided to an internal circumference portion of bottom surface of the contact plate 274. In this state, the plating solution injection nozzle 280 provides a plating solution. A plating solution is provided to a plating surface of the substrate W by way of the injection plate 281 and the plating solution agitation member 290. When a power supply is connected to the anode electrode 276, an electron having an electrical negative property moves from the anode electrode 276 to a seed layer of the substrate W and a positive ion of metal having an electrical positive property dissolves in a plating solution. If electrons gather on a seed layer of the substrate, the electrons pulls positive ions of metal dissolved in a plating solution and thereby a plating layer is formed on the seed layer of the substrate.

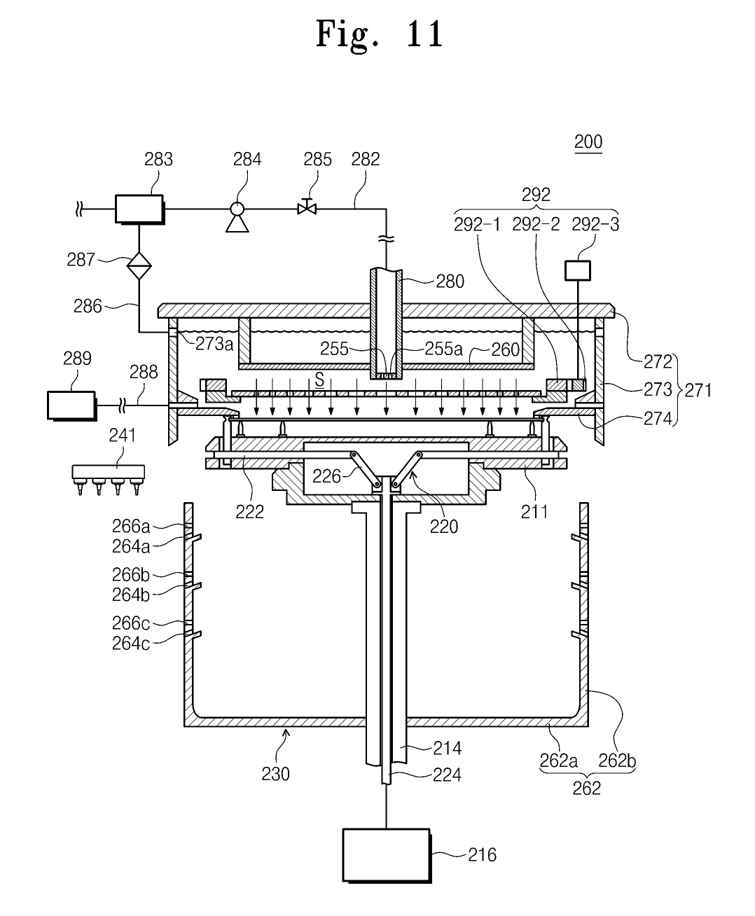

A plating solution is continuously provided during a plating process and when a level of the plating solution becomes higher than a specific level, the plating solution is drained through the overflow hole 273a formed on the sidewall 273 of the plating bath 271. The drained plating solution flows in the plating solution tank 283 through the circulation line 286 and the plating solution flowed in the plating solution tank 283 is resupplied to the plating solution injection nozzle 280 through the plating solution supply line 282. If the plating process is completed, a plating solution in the plating bath 271 is discharged through the discharge hole 273b formed on the sidewall 273. (FIG. 11)

If the plating process is completed, the spin chuck 211 moves down to the first position in which a wet process is performed by the shaft driver 216 and the drip bath 295 returns to the space between the collection container 262 and the plating bath 271 by the driving portion 296.

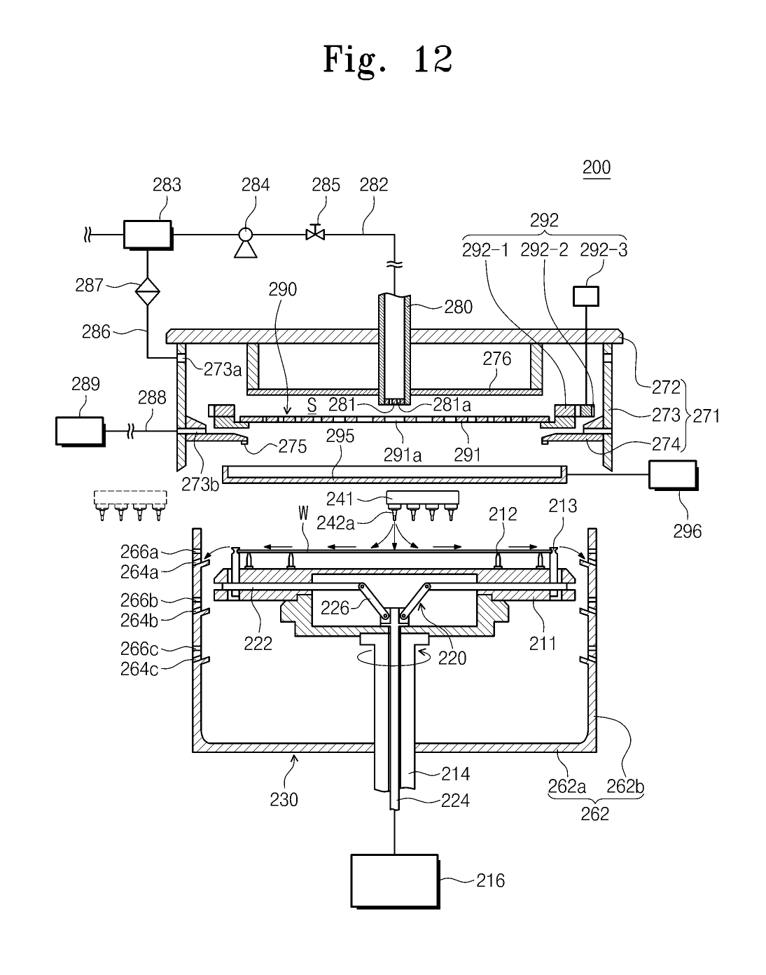

The deionized water nozzle 242a is moved to a location at the center of the upper portion of the substrate W by a movement of the nozzle arm 241. The deionized water nozzle 242a injects deionized water for a rinse process onto a plating surface of the substrate W and the substrate W rotates as the spin chuck 211 is rotated by the chuck driver 216. Deionized water being displaced by a rotation of the substrate W is collected through the first collection hole 264a. (FIG. 12).

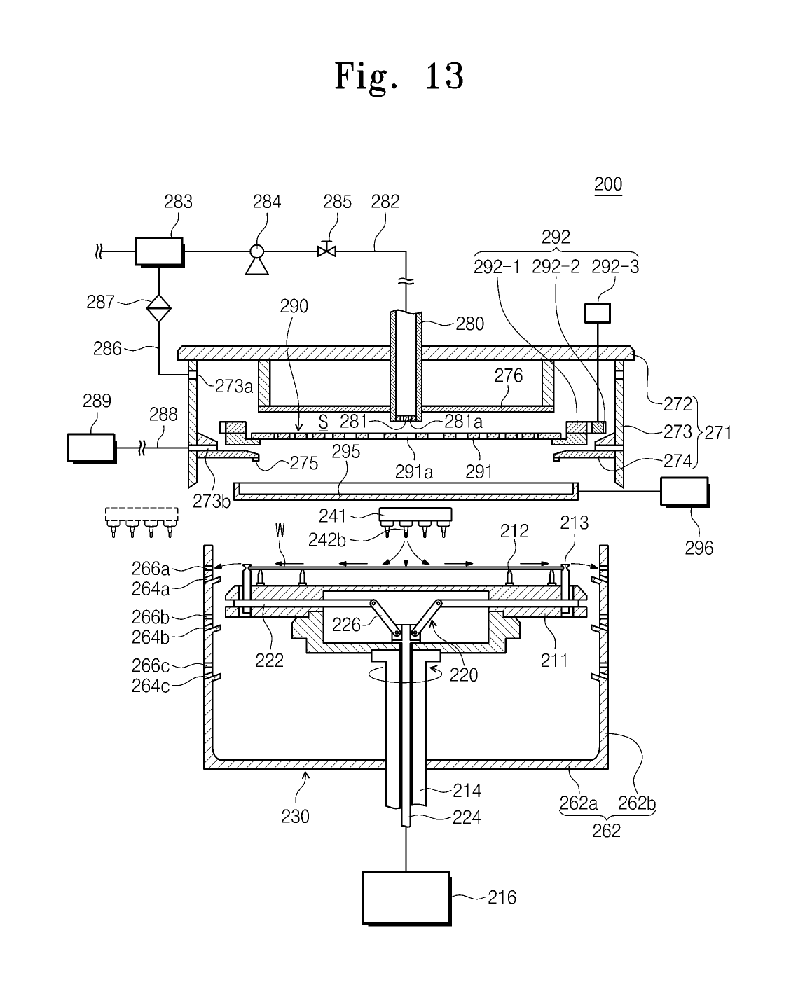

If the rinse process is completed, the dry gas nozzle 242b is located at the center of the upper portion of the substrate W by a movement of the nozzle arm 241. The dry gas nozzle 242b provides a dry gas to the substrate W being rotated to dry the substrate W. At this time, a dry gas used to dry the substrate W is exhausted through the first exhaust hole 266a. (FIG. 13)

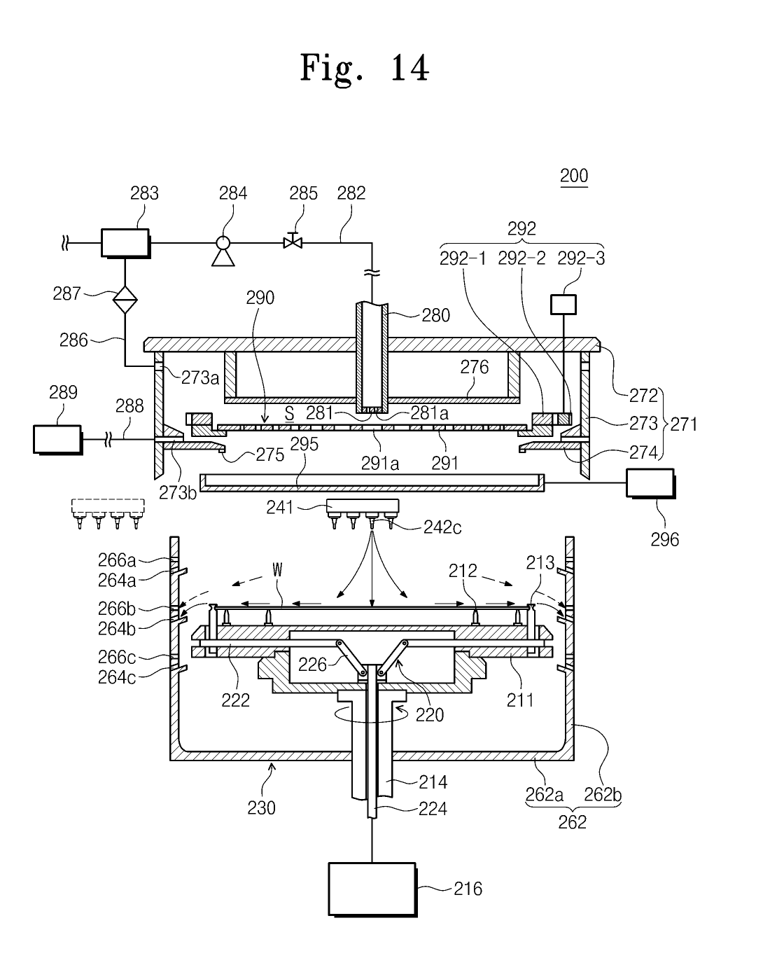

If the rinse and dry processes are completed, the spin chuck 211 moves a second position lower than the first position by the shaft driver 216 and the organic solvent nozzle 242c is located at the center of the upper portion of the substrate W by a movement of the nozzle arm 241. The organic solvent nozzle 242c provides an organic solvent to the substrate W being rotated to remove a photoresist pattern. An organic solvent being displaced by a rotation of the substrate W is collected through the second collection hole 264b and the atmosphere including the organic solvent ingredient is exhausted through the second exhaust hole 266b. (FIG. 14)

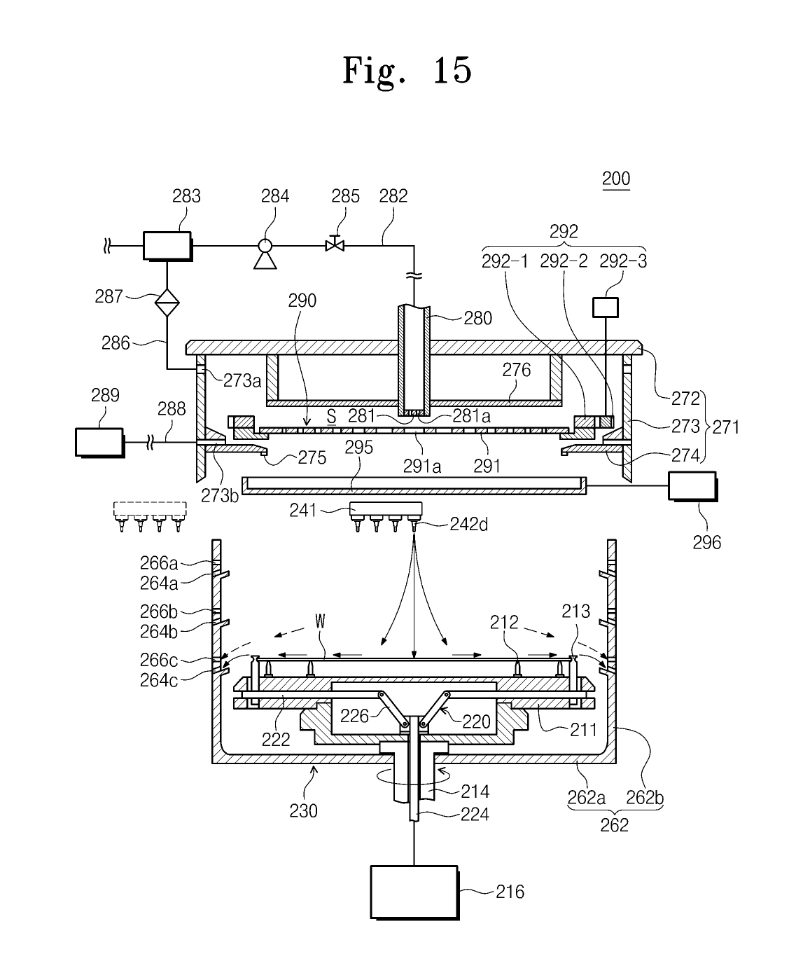

If the photoresist removing process is completed, a rinse and dry process may be performed using the method illustrated in FIGS. 12 and 13. If the rinse and dry process is completed, the spin chuck 211 moves to a third position lower than the second position by the shaft driver 216 and the etching solution nozzle 242d is located at the center of the upper portion of the substrate W by a movement of the nozzle arm 241. The etching solution nozzle 242d provides an etching solution to the substrate W being rotated to etch the remaining seed layers except the seed layer under the plating layer. An etching solution being scattered by a rotation of the substrate W is collected through the third collection hole 264c and the atmosphere including the etching solution ingredient is exhausted through the third exhaust hole 266c. (FIG. 15)

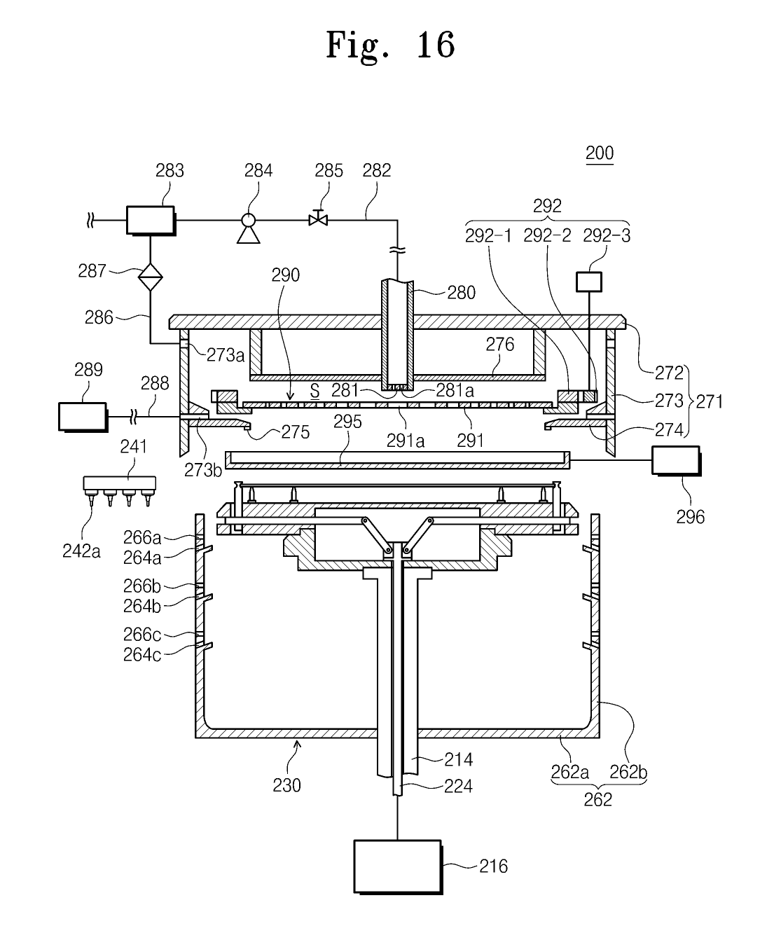

If the etching process is completed, a rinse and dry process may be performed using the method illustrated in FIGS. 12 and 13. If the rinse and dry process is completed, the nozzle arm 241 moves to the standby position and the spin chuck 211 is gone up by the shaft driver 216 so that the support pins 212 and the chuck pins 213 upwardly protrude from the collection container 262. The substrate W is unchucked from the chuck pins 213 and is unloaded from the process chamber by the main transferring robot 24. (FIG. 16)

According to the inventive concepts, a plating process, and a photoresist removing process and a seed layer etching process which are subsequent processes of the plating process can be continuously performed in one facility.

According to the inventive concepts, a turn around time (TAT) taken in performing a plating process, a photoresist removing process and a seed layer etching process can be reduced.

Also, according to the inventive concepts, deterioration of a plating quality due to a delay of a process proceeding can be prevented or reduced.

The above-disclosed subject matter is to be considered illustrative, and not restrictive, and the appended claims are intended to cover all such modifications, enhancements, and other embodiments, which fall within the true spirit and scope of the inventive concepts. Thus, to the maximum extent allowed by law, the scope of the inventive concepts is to be determined by the broadest permissible interpretation of the following claims and their equivalents, and shall not be restricted or limited by the foregoing detailed description.

1. A substrate treating device, comprising:
a plating treatment portion configured to perform a plating process of a substrate;
a wet treatment portion configured to perform a wet treating process of the substrate, the wet treatment portion being under the plating treatment portion; and
a substrate support portion configured to support the substrate so that a plating surface of the substrate faces upward, the substrate support portion being further configured to move the substrate between the plating treatment portion and the wet treatment portion.

2. The substrate treating device of claim 1, wherein
the substrate support portion includes a spin chuck configured to restrain the substrate, a driving shaft coupled to a lower portion of the spin chuck, and a shaft driver configured to rotate and move up and down the driving shaft, and
the wet treatment portion includes a treating fluid supply member configured to supply a wet treating fluid to the substrate.

3. The substrate treating device of claim 2, wherein the treating fluid supply member comprises:
an organic solvent nozzle configured to supply an organic solvent to the substrate, the organic solvent for removing a photoresist from the substrate.

4. The substrate treating device of claim 3, wherein the treating fluid supply member further comprises:
an etching solution nozzle configured to supply an etching solution to the substrate.

5. The substrate treating device of claim 4, wherein the treating fluid supply member further comprises:
a deionized water nozzle configured to supply deionized water to the substrate; and
a dry gas nozzle configured to supply a dry gas to the substrate.

6. The substrate treating device of claim 5, wherein the treating fluid supply member further comprises:
a nozzle arm in which the organic solvent nozzle, the etching solution nozzle, the deionized water nozzle and the dry gas nozzle are attached; and
a nozzle arm driving portion configured to move the nozzle arm between a process position above an upper portion of the substrate and a standby position at a side of the substrate.

7. The substrate treating device of claim 5, wherein
the wet treatment portion further includes a treating fluid collection member configured to collect the wet treating fluid, the wet treating fluid being displaced by a rotation of the substrate, the treating fluid collection member including, a collection container having at least one vertical wall surrounding the substrate support portion, and the at least one vertical wall including collection holes provided at different heights so as to separately collect the deionized water, the organic solvent, and the etching solution.

8. The substrate treating device of claim 7, wherein the at least one vertical wall further includes exhaust holes adjacent to the collection holes, the exhaust holes being arranged above the collection holes.

9. The substrate treating device of claim 7, wherein the plating treatment portion comprises:
a plating bath having a container of which a lower portion is open, the plating bath facing an upper portion of the collection container;
a contact plate having a ring shape and being coupled to the opened lower portion of the plating bath, the contact plate including a contact portion configured to contact the plating surface of the substrate, the contact portion being arranged in an internal circumference portion of a bottom surface of the contact plate;
an anode electrode in the plating bath;
a power supply configured to apply a voltage to the anode electrode, the power supply including metal pins arranged in the contact portion; and
a plating solution injection nozzle configured to supply a plating solution into the plating bath.

10. The substrate treating device of claim 9, wherein the spin chuck includes chuck pins configured to restrain an edge of the substrate, the chuck pins being arranged on an edge portion of the spin chuck and located outside of the contact portion in a radial direction when the plating surface of the substrate is in contact with the contact portion.

11. The substrate treating device of claim 9, wherein the plating treatment portion further comprises:
a drip bath between the opened lower portion of the plating bath and the upper portion of the collection container, the drip bath configured to receive the plating solution from the plating bath, and
a drip bath driver configured to move the drip bath between an inside and an outside of a space between the plating bath and the collection container.

12-20. (canceled)
